(19) United States
(12) Patent Application Publication
(10) Pub. No.: US 2025/0219727 A1
(43) Pub. Date: Jul. 3, 2025

(54) PASSIVE OPTICAL NETWORK PERFORMANCE PARAMETER MEASUREMENT AND ONLINE RECONFIGURATION

(71) Applicant: MaxLinear, Inc., Carlsbad, CA (US)

(72) Inventors: Gert Schedelbeck, München (DE); Rainer Strobel, München (DE); Vladimir Oksman, Morganville, NJ (US)

(73) Assignee: MaxLinear, Inc., Carlsbad, CA (US)

(21) Appl. No.: 18/851,678

(22) PCT Filed: Apr. 3, 2023
(86) PCT No.: PCT/US2023/017354

§ 371 Date: Sep. 26, 2024

Related U.S. Application Data
(60) Provisional application No. 63/362,386, filed on Apr. 1, 2022.

(51) Int. Cl. H04B 10/079; H04Q 11/00

(52) U.S. Cl. CPC H04B 10/0795; H04Q 11/0067; H04Q 2011/0083

(57) ABSTRACT

According to an aspect of an embodiment, an optical network unit (ONU) in a passive optical network (PON) may comprise a physical media dependent (PMD) receiver, a detector, and a processing device. The PMD receiver may be configured to receive a downstream signal from an optical line terminal (OLT). The detector may be configured to measure a link quality parameter in the downstream signal. The processing device may be configured to identify a link quality parameter target, wherein the link quality parameter target is a value that achieves a target error probability. The processing device may be configured to compute a link quality parameter margin between the measured link quality parameter and the link quality parameter target, and adjust a transmission parameter based on the link quality parameter margin.

### RELATED APPLICATION

This application claims the benefit of U.S. Provisional Application No. 63/362,386, filed Apr. 1, 2022, the disclosures of which are incorporated herein by reference in its entirety.

The embodiments discussed in the present disclosure are related to passive optical network performance parameter measurement and online reconfiguration.

### BACKGROUND

Unless otherwise indicated herein, the materials described herein are not prior art to the claims in the present application and are not admitted to be prior art by inclusion in this section.

Passive optical networks (PONs) may include an optical line terminal (OLT) that may be connected to one or more optical network units (ONUs). Transmissions from the OLT to the one or more ONUs may include a broadcast that may be received by all ONUs included in the PON.

The subject matter claimed in the present disclosure is not limited to embodiments that solve any disadvantages or that operate only in environments such as those described above. Rather, this background is only provided to illustrate one example technology area where some embodiments described in the present disclosure may be practiced.

### SUMMARY

In some embodiments, an optical network unit (ONU) in a passive optical network (PON) may comprise a physical media dependent (PMD) receiver, a detector, and a processing device. The PMD receiver may be configured to receive a downstream signal from an optical line terminal (OLT). The detector may be configured to measure a link quality parameter in the downstream signal. The processing device may be configured to identify a link quality parameter target, wherein the link quality parameter target is a value that achieves a target error probability. The processing device may be configured to compute a link quality parameter margin between the measured link quality parameter and the link quality parameter target, and adjust a transmission parameter based on the link quality parameter margin.

In some embodiments, an OLT in a PON may comprise a PMD receiver, at the OLT, configured to receive one or more upstream signals from one or more ONUs. The OLT may comprise a detector, at the OLT, configured to measure a link quality parameter in the one or more upstream signals. The OLT may comprise a processing device configured to: identify a link quality parameter target, wherein the link quality parameter target is the value of the link quality parameter that achieves a target error probability. The processing device may be configured to adjust a burst parameter based on the link quality parameter target.

In some embodiments, a method for online reconfiguration in a passive optical network may comprise performing, at a central optical node, a link quality parameter measurement. The method may comprise identifying, at the central optical node, a link quality parameter margin based on the link quality parameter measurement. The method may comprise computing, at the central optical node, an updated link setting based on the link quality parameter margin. The method may comprise applying the updated link setting.

The objects and advantages of the embodiments will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1 illustrates an example passive optical network.

FIG. 2A illustrates an example passive optical network transmission model for a downstream direction.

FIG. 2B illustrates an example passive optical network transmission model for an upstream direction.

FIG. 3 illustrates the relationship between a signal-to-noise ratio (SNR) and generalized mutual information (GMI) for various modulation settings.

FIG. 4A illustrates an example process flow of a passive optical network for online reconfiguration.

FIG. 4B illustrates an example process flow of a passive optical network for online reconfiguration.

FIG. 5A illustrates an example process flow of a passive optical network for performance parameter measurement.

FIG. 5B illustrates an example process flow of a passive optical network for performance parameter measurement.

FIG. 6 illustrates an example communication system.

FIG. 7 illustrates an example process flow of a passive optical network for performance parameter measurement.

FIG. 8 illustrates an example process flow of a passive optical network for performance parameter measurement.

FIG. 9 illustrates an example process flow of a passive optical network for online reconfiguration.

FIG. 10 illustrates a diagrammatic representation of a machine in the example form of a computing device within which a set of instructions, for causing the machine to perform any one or more of the methods discussed herein, may be executed.

### DESCRIPTION OF EMBODIMENTS

In previous generation passive optical networks, transmission parameters such as modulation type and FEC code settings were fixed. The performance monitoring parameters included the pre-FEC and post-FEC bit error counters, the counter of corrected errors, and the received optical power.

In contrast to previous PON generations, PON systems such as 50G PON may benefit from adjustment of various transmission parameters such as an error correction code (e.g., a forward error correction (FEC) code) settings, interleaver settings, and modulation type. These transmission parameter settings may be adjusted individually for each ONU to adapt to the different channel conditions for each ONU.

For 50G PON, FEC parameters may be selected based on trial-and error (e.g., use more robust FEC settings when transmission errors occur), bit error rate counters, and/or corrected error counters. Bit error rate counters for performance monitoring may not provide useful information. When low-density parity-check (LDPC) codes are used in 50G PON for error correction, the post-FEC bit error rates may increase from e.g., below 10⁻¹² bit error ratio, to e.g., about 10⁻², which may cause a complete loss of transmission with a small change in the transmission parameters (e.g., a decrease of receive power by 0.5 dB).

In contrast, pre-FEC bit errors may not provide useful information about the receiver implementation, e.g., the input bit error ratio that is used by a certain ONU to achieve the target output bit error probabilities. In addition, pre-FEC bit errors may be misleading because the signal quality may depend on the probability of errors and on the error distribution over time. As an example, bursts of errors within one FEC codeword may cause FEC failures when the average bit error probability is low.

Another performance parameter is the received optical power. Similar to the raw bit error ratio (BER), the received optical power may not be based on the receiver implementation and may not provide useful information about the margin, e.g., the decrease in transmit power (or increase in attenuation) that does not violate an error rate limit.

In contrast to the other approaches, link quality parameters may be based on the receiver capabilities to report the link quality parameter margins. Bit error ratios may be too low to be estimated accurately for a high link quality, but the SNR and GMI may provide useful information related to the receiver capabilities. In addition, performance impacting factors like nonlinear distortion or correlated errors may be used. Furthermore, transmission parameters to and from each particular ONU may be dynamically adjusted based on the receiver operation and settings for each ONU in the PON system.

Because of the increasing transmission rates of passive optical networks (PON) and the decreasing performance margins, performance monitoring and system adaptation has become more useful. Furthermore, the channel quality for individual users may be enhanced based on the transmission methods.

The present disclosure provide techniques for online reconfiguration to adjust transmission parameters to the current channel conditions. Link quality parameters and link quality parameter margins may be used to select transmission parameters such as FEC settings, interleaver settings, and modulation type. In addition, these link quality parameters and link quality parameter margins may be used to detect network failures and to reconfigure the network in response.

In some embodiments, an optical network unit (ONU) in a passive optical network (PON) may comprise a physical media dependent (PMD) receiver, a detector, and a processing device. The PMD receiver may be configured to receive a downstream signal from an optical line terminal (OLT). The detector may be configured to measure a link quality parameter in the downstream signal. The processing device may be configured to identify a link quality parameter target, wherein the link quality parameter target is a value that achieves a target error probability. The processing device may be configured to compute a link quality parameter margin between the measured link quality parameter and the link quality parameter target, and adjust a transmission parameter based on the link quality parameter margin.

In some embodiments, an OLT in a PON may comprise a PMD receiver, at the OLT, configured to receive one or more upstream signals from one or more ONUs. The OLT may comprise a detector configured to measure a link quality parameter in the one or more upstream signals. The OLT may comprise a processing device configured to: identify a link quality parameter target, wherein the link quality parameter target is the value of the link quality parameter that achieves a target error probability. The processing device may be configured to adjust a burst parameter based on the link quality parameter target.

In some embodiments, a method for online reconfiguration in a passive optical network may comprise performing, at a central optical node, a link quality parameter measurement. The method may comprise identifying, at the central optical node, a link quality parameter margin based on the link quality parameter measurement. The method may comprise computing, at the central optical node, an updated link setting based on the link quality parameter margin. The method may comprise applying the updated link setting.

Embodiments of the present disclosure will be explained with reference to the accompanying drawings.

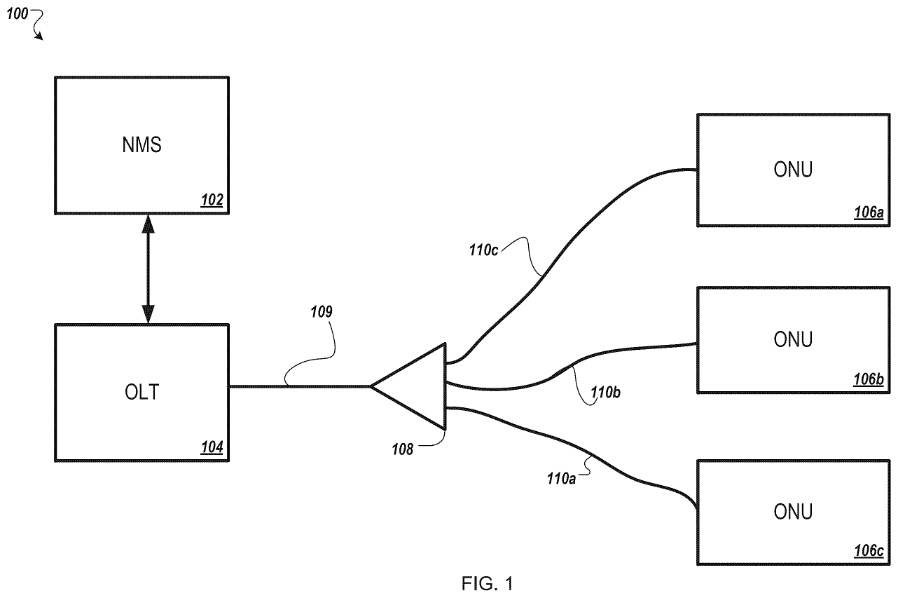

In some embodiments, as illustrated in FIG. 1, a passive optical network (PON) 100 may comprise a network management system (NMS) 102, one or more optical line terminals (OLTs) 104, and one or more optical network units (ONUs) 106a, 106b, 106c. The PON 100 may be a point-to-multipoint network in which the one or more ONUs 106a, 106b, 106c may be directly or indirectly coupled to the one or more OLTs 104 via a passive splitter 108 and one or more fibers 109, 110a, 110b, 110c. Transmissions from the one or more OLTs 104 may be received by the one or more ONUs 106a, 106b, 106c. Transmission from the one or more ONUs 106a, 106b, 106c may be received by the one or more OLTs 104. The one or more OLTs 104 or the one or more ONUs 106a, 106b, 106c may be configured to convert the received optical signal to an electrical signal. The NMS 102 may be coupled to the one or more OLTs 104 and may configure and monitor the PON 100.

In some embodiments, one OLT 104 may be directly or indirectly coupled to a plurality of ONUs 106a, 106b, 106c. Alternatively, or in addition, a plurality of OLTs 104 may be directly or indirectly coupled to the plurality of ONUs 106a, 106b, 106c. When a plurality of OLTs 104 are directly or indirectly coupled to the plurality of ONUs 106a, 106b, 106c, the plurality of OLTs 104 may comprise a primary OLT 104 and a secondary OLT. The secondary OLT may replace the functionality of the primary OLT 104 when the primary OLT 104 becomes inoperable. Alternatively, or in addition, the secondary OLT may operate in parallel with the primary OLT 104 to enhance the primary OLT's 104 functionality as disclosed herein.

In some embodiments, a link quality parameter measurement may be used to switch between a primary OLT 104 and a secondary OLT. In one example, a link quality parameter may indicate a switch from the primary OLT to the secondary OLT when the link quality parameter measurement at the primary OLT and at the secondary OLT indicates that: (i) the link quality for the secondary OLT is greater than the link quality for the primary OLT, (ii) the link quality for the primary OLT is below a threshold for transmitting or receiving an optical signal, or (iii) the link quality for the secondary OLT is above a threshold for transmitting or receiving an optical signal. In some examples, the primary OLT and the secondary OLT may be operable on different wavelengths, and, when specific wavelengths for the secondary OLT facilitate a higher link quality compared to the wavelengths for the primary OLT, the secondary OLT may replace the functionality of the primary OLT.

In some embodiments, the direction of transmission between OLTs 104 and ONUs 106a, 106b, and 106c may be in a downstream direction or in an upstream direction. In the downstream direction (i.e., the direction from the one or more OLTs 104 to the one or more ONUs 106a, 106b, 106c), a data stream may be transmitted from the OLT 104 as a broadcast in which all connected ONUs 106a, 106b, 106c) receive the data stream. In the upstream direction (i.e., the direction from the one or more ONUs 106a, 106b, 106c to the one or more ONUs 106a, 106b, 106c), time slots for transmission may be allocated for each ONU 106a, 106b, 106c based on traffic usage requested by a user.

In some embodiments, measurements performed at the receiver side (e.g., at the ONU 106a, 106b, 106c for a downstream direction or at the OLT 104 for an upstream direction) may be used to monitor the link quality and performance for various parameters. For downstream transmission, measurements may be performed at the ONU 106a, 106b, 106c and communicated to the OLT 104. For upstream transmission, the measurement may be performed at the OLT 104.

In some embodiments, information relating to link quality and performance of both upstream links and downstream links may be used at the OLT, or alternatively, or in addition, communicated to a central NMS. Based on the reported parameters, the OLT, under control of the NMS, may modify transmission parameters and transmission modes for both the upstream transmission and downstream transmission that are used to configure and reconfigure the network.

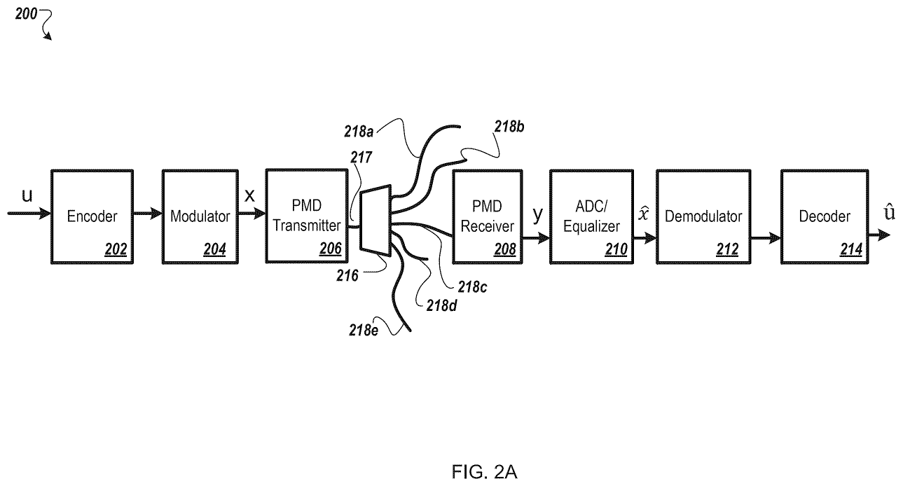

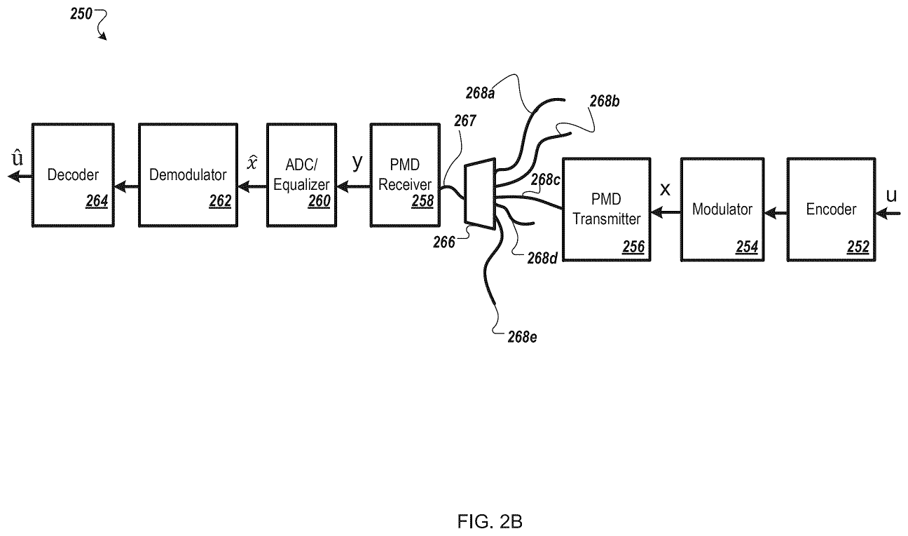

In some embodiments, as illustrated in FIG. 2A, a passive optical network transmission model 200 for a downstream direction may comprise an encoder 202, a modulator 204, a physical media dependent (PMD) transmitter 206, a passive splitter 216, one or more fibers 217, 218a, 218b, 218c, 218d, 218e directly or indirectly coupling the PMD transmitter 206 and a PMD receiver 208, an analog-to-digital converter (ADC) and/or equalizer 210, a demodulator 212, a decoder 214, or the like.

In some embodiments, a transmit bit sequence u may be encoded at the encoder 202 (e.g., a forward error correction (FEC) encoder) and modulated at the modulator 204 to generate a transmit signal x that may be converted to an optical signal in the PMD transmitter 206. The optical signal may be transmitted over one or more fibers (e.g., 217, 218c) and one or more splitters (e.g., passive splitter 216) to the receiver side (e.g., the ONU). At the ONU, the PMD receiver 208 may convert the optical signal back to an electrical signal y. Based on the electrical signal, y, the ADC/Equalizer 210 may obtain a recovered signal, \hat{x}, which may be: (i) demodulated at the demodulator 212, using log likelihood ratio (LLR) calculations and (ii) decoded at the decoder 214 (e.g., an FEC decoder) to recover the transmitted bit sequence û.

In some embodiments, as illustrated in FIG. 2B, a passive optical network transmission model 250 for an upstream direction may comprise one or more of an encoder 252, a modulator 254, a PMD transmitter 256, one or more fibers 268a, 268b, 268c, 268d, 268e, 267, a PMD receiver 258, an ADC/Equalizer 260, a demodulator 262, a decoder 264, or the like.

In some embodiments, a transmit bit sequence u may be encoded at the encoder 252 at the ONU. The encoder 252 may comprise an FEC encoder. The transmit bit sequence, after being encoded, may be modulated at the modulator 254 to generate a transmit signal x which may be converted to an optical signal in the PMD transmitter 256. The optical signal may be transmitted over the fiber 268c, the passive splitter 266, and the fiber 267 to the receiver side (e.g., the OLT). At the OLT, the PMD receiver 258 may convert the optical signal back to an electrical signal y. Based on the electrical signal y, the ADC/Equalizer 260 may obtain the recovered signal \hat{x}, which may be: (i) demodulated at the demodulator 262, using log likelihood ratio (LLR) calculations and (ii) decoded at the decoder 264 (e.g., an FEC decoder) to recover the transmitted bit sequence û.

In some embodiments, not all of the blocks illustrated in FIGS. 2A and 2B may be present. For example, transmission systems supporting only non-return-to-zero (NRZ) modulation format may omit the modulate or demodulate operations. Other implementations may not use digital equalization, e.g., when inter-symbol interference may be negligible.

In some embodiments, a PON 200, 250 may use link quality parameters that may be based on the capabilities of the particular decoder 214, 264 (e.g., an FEC decoder, such as a low density parity check (LDPC) decoder) and the particular digital equalizer 210, 260. The link quality parameters may measure the margins for a particular receiver (e.g., at an ONU or an OLT) to achieve a fixed reference link quality as provided by e.g., the target post-FEC bit error probability, the packet error probability, the codeword error probability, or the like.

In some embodiments, an ONU may comprise a PMD receiver (e.g., 208) that may be configured to receive a downstream signal from an OLT, and a detector configured to measure a link quality parameter in the downstream signal. The link quality parameter may be one or more of a signal-to-noise ratio (SNR), generalized mutual information (GMI), a transmit power (e.g., optical transmit power), or the like.

The ONU may comprise a processing device configured to identify a link quality parameter target. The link quality parameter target may be a value that achieves a target error probability. In some embodiments, the target error probability may be one or more of a post forward error correction (FEC) error probability, a packet error probability, a codeword error probability, a symbol error rate, a bit error rate, or the like. In some examples, a value for the target error probability may be defined by a standard (e.g., International Telecommunication Union (ITU) Telecommunication Standardization Sector (ITU-T) G.9804.2, e.g., a target output bit error rate of 10⁻¹², or a codeword error rate below 10⁻⁹, or an LDPC decoding error probability of less than 10⁻⁶). Alternatively, or in addition, a value for the target error probability may be any suitable value of from about 10⁻³ to about 10⁻¹⁵ that may be achieved by a value for a link quality parameter target. Alternatively, or in addition, the target error probability may be defined the NMS.

The processing device may be configured to compute a link quality parameter margin between the measured link quality parameter and the link quality parameter target. The processing device may be configured to adjust a transmission parameter based on the link quality parameter margin. The transmission parameters may include any suitable parameters such as a modulation type, an error correction code (ECC) setting, an interleaver setting, a transmit power setting, or the like.

In some embodiments, the link quality parameter may be a signal to noise ratio (SNR). The SNR may be computed using the equalizer 210, 260 output signal (e.g., as \hat{x}) or using the equalizer 210, 260 input signal (e.g., as y). The SNR as measured at the equalizer 210, 260 output signal (e.g., as \hat{x}) may provide a transmission quality that includes the digital receiver. The SNR as measured at the equalizer 210, 260 input (e.g., as y) may depend on optical components without including the contribution from the digital receiver.

In some examples, the SNR may be the ratio between the signal power and the noise power. In an example, the signal-to-noise ratio of the received electrical signal y, at the input of the equalizer 210, 260 may be computed using:

$$S N {R}_{i n} = \frac{{\sum }_{t} {\vert {x}_{t} \vert}^{2}}{{\sum }_{t} {\vert {gy}_{t} - {x}_{t} \vert}^{2}}$$

where g is a constant to bring the signal y to the same scale as the transmit signal x. In some examples, the SNR at the equalizer output signal \hat{x}, may be computed using:

$$SN {R}_{out} = \frac{{\sum }_{t} {\vert {x}_{t} \vert}^{2}}{{\sum }_{t} {\vert {\hat{x}}_{t} - x \vert}^{2}}$$

The SNR as measured at the equalizer 210, 260 input or output may be computed as an average over T samples at time instances t=1, . . . , T.

In some embodiments, the SNR may be computed in various ways. In one example, the SNR measurement may be performed on a reference signal that may be known to the receiver. In some embodiments, the reference signal may be the transmitted signal x. The transmitted signal x may be used to compute the SNR by re-encoding and/or re-modulating the decoding output, û, to generate the transmitted signal x.

In some embodiments, the reference signal may be a downstream physical synchronization block (PSBd) or an upstream physical synchronization block (PSBu). In one example, the PSBd in the downstream frame may comprise (i) the Psync pattern, (ii) the superframe counter (SFC), and (iii) the operation control (OC) structure. The SNR measurement may similarly be performed on the PSBu in the upstream frame.

In some embodiments, the equalizer output signal \hat{x} may be used to compute the SNR. This may be achieved by applying a hard decision threshold to the equalizer output \hat{x} to obtain the recovered transmit signal x. The hard decision threshold may recover the transmitted signal x by assigning a ‘1’ when the level of the equalizer output signal is above the hard decision threshold and assigning a ‘0’ when the level of the equalizer output signal is below the hard decision threshold.

In some embodiments, a link quality parameter margin may be computed by: (i) measuring a link quality parameter, (ii) identifying a link quality parameter target (ii) and (ii) computing a margin between the measured link quality parameter and the link quality parameter target.

In some embodiments, to compute the SNR margin (SNRₘ) based on the SNR, the SNR target to achieve the target error probability may be identified. The SNR target may be based on the modulation format, the ECC settings (e.g., FCC settings), the interleaver settings, the signal characteristics, or the like. The SNR margin may be computed using:

$$S N {R}_{m} [ dB ] = S N {R}_{o u t} [ dB ] - S N {R}_{tar} [ dB ] .$$

The values of SNRₜₐᵣ may be computed using offline simulations and stored at the ONU receiver or the OLT receiver.

In some embodiments, the reported SNR performance parameters may include one or more of: SNRᵢₙ (in dB), SNRₒᵤₜ (in dB), SNRₘ (in dB). The reported SNR and SNR margin may be computed from the equalizer output and may include a performance monitoring parameter that may be based on the receiver characteristics. The SNR performance parameters and the performance monitoring parameter may be computed on a low quality connection where error counters may be less reliable.

In some embodiments, the ONU may comprise a non-linear equalizer. The non-linear equalizer may be used to compute the SNRᵢₙ or SNRₒᵤₜ in cases in which the SNR margin computation may be distorted by: (i) non-linear distortion, (ii) statistical dependencies in the equalizer output signal when interleaving is not used, or (iii) when non-linear equalizers are used (e.g., a maximum likelihood sequence estimation (MLSE) equalizer or a Bahl-Cocke-Jelinek-Raviv (BCJR) equalizer). The non-linear equalizers may output the most probable bit sequence, when MLSE is used, or the LLR values, when BCJR is used. When non-linear equalizers are used, the SNR and SNR margin may be computed based on the GMI.

In some embodiments, the link quality parameter may be GMI. The GMI may be measured based on one or more of an equalizer input signal, an equalizer output signal, a demodulator output signal, a decoder input signal, an internal decoding parameter, or a decoder output signal. Alternatively, or in addition, the GMI may be computed based on the SNR.

In some embodiments, GMI may be a measure of the mutual information per transmitted bit at the receiver (e.g., at the ONU or the OLT). For an arbitrary discrete (quantized) receive signal \hat{x}∈X, mutual information I may be computed using:

$$I = {\sum }_{x ∈ 0 , 1} {\sum }_{\hat{x} ∈ X} {p}_{x \hat{x}} ( x , \hat{x} ) {log}_{2} ( \frac{{p}_{x \hat{x}} ( x , \hat{x} )}{{p}_{x} ( x ) {p}_{\hat{x}} ( \hat{x} )} ) ,$$

where p_{x\hat{x}}(x, \hat{x}) may be the probability to transmit x and receive \hat{x}; pₓ(x) may be the probability to transmit x (e.g., pₓ(x)=0.5); and p_{\hat{x}}(\hat{x}) may be the probability to receive \hat{x}, (i.e., p_{\hat{x}}(\hat{x})=p_{x\hat{x}}(x=0, \hat{x})+p_{x\hat{x}}(x=1, \hat{x}).

In some embodiments, the GMI and the GMI margin may be computed at the demodulator output. In one example, the LLR values L may be computed using:

$$I = {\sum }_{x ∈ 0 , 1} {\sum }_{L ∈ X} {p}_{x L} ( x , L ) {log}_{2} ( \frac{{p}_{x L} ( x , L )}{{p}_{x} ( x ) {p}_{L} ( L )} ) .$$

GMI may be computed at the receiver side by computing the probability p_{xL}(x, L).

In some embodiments, GMI may be computed in various ways. In one example, the GMI measurement may be performed on a reference signal that may be known to the receiver. In some embodiments, the reference signal may be the transmitted signal x. The transmitted signal x may be used to compute the GMI by re-encoding and/or re-modulating the decoding output, û, to generate the transmitted signal x. In some embodiments, the reference signal may be a downstream physical synchronization block (PSBd) or an upstream physical synchronization block (PSBu).

In some embodiments, the equalizer output signal \hat{x} may be used to compute the GMI. This may be achieved by applying a hard decision threshold to the equalizer output \hat{x} to obtain the recovered transmit signal x. The hard decision threshold may recover the transmitted signal x by assigning a ‘1’ when the level of the equalizer output signal is above the hard decision threshold and assigning a ‘0’ when the level of the equalizer output signal is below the hard decision threshold.

In some embodiments, for a number of transmitted bits xₜ, the number of occurrences of each received signal amplitude x or LLR value L may be counted. The probability may be approximated using

$${p}_{x L} ( x , L ) \approx \frac{{N}_{x , L}}{T} ,$$

where T is the number of transmitted bits and N_{x,L} is the number of occurrences of L at the receiver when x is transmitted.

In some embodiments, the reported GMI performance parameters may include one or more of: GMI I (in bits), or GMI margin Iₘ (in bits). To compute the GMI margin Iₘ, the target GMI, Iₜₐᵣ may be used, which may be computed in off-line simulations or measurements that may be stored in the receiver for different modulation types, ECC settings, interleaver settings, transmit power settings, or the like.

In some embodiments, the SNR margin may be computed based on the GMI for receiver architectures with non-linear equalizers in which a direct SNR evaluation may not be feasible. In some embodiments, the link quality parameter may be an SNR that has been computed based on a GMI. The SNR may be computed based on the GMI using one or more of a channel capacity gap, a modulation-based reference curve, or the like.

In some embodiments, a correspondence between the SNR and GMI may be used to compute the SNR based on the GMI or compute the GMI based on the SNR. For the additive white Gaussian noise (AWGN) channel with Gaussian modulation, when mutual information has a maximum value, the value of per-bit channel capacity C may be computed using:

$$C = {log}_{2} ( 1 + S N R ) .$$

Because the implemented modulation scheme may not achieve full channel capacity, a gap to capacity Γ may occur. The mutual information may be computed using:

$$I = {log}_{2} ( 1 + \frac{S N R}{Γ} ) .$$

The receiver behavior may be approximated with a value of Γ, such that mutual information may be converted into GMI. The SNR margin may be computed using:

$$S N {R}_{m} [ dB ] = 10 {log}_{10} ( {2}^{I} - 1 ) - 10 {log}_{10} ( {2}^{{I}_{t a r}} - 1 ) .$$

In some embodiments, the SNR may be computed based on the GMI using a reference curve. The computation of the SNR from the reference curve may be dependent on the modulation format. The computation may use modulation formats including 2-pulse amplitude modulation (2-PAM), pulse amplitude modulation level 4 (PAM-4), Gaussian modulation, or the like.

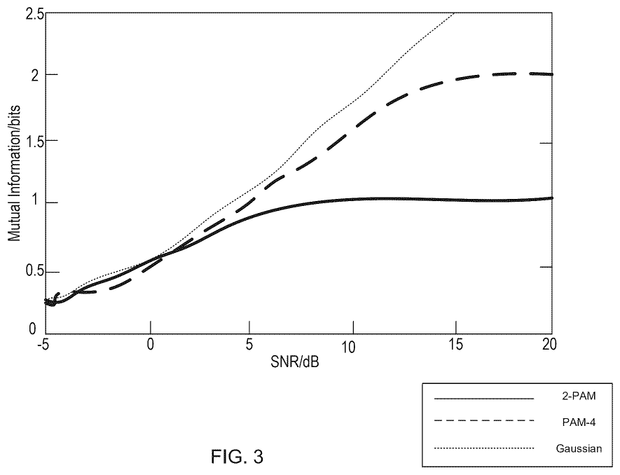

As illustrated in FIG. 3, for 2-PAM, the values in mutual information per bits may range from about 0.25 mutual information per bits (when the SNR/dB is about −5) to about 1 mutual information per bits (when the SNR/dB is greater than about 5). For PAM-4, the values in mutual information per bits may range from about 0.25 mutual information per bits (when the SNR/dB is about −5), to about 1 mutual information per bits (when the SNR/dB is about 5), to about 1.5 mutual information per bits (when the SNR/dB is about 10), to about 2 mutual information per bits (when the SNR/dB is greater than about 13). For Gaussian modulation, the values in mutual information per bits may range from about 0.25 mutual information per bits (when the SNR/dB is about −5), to about 1 mutual information per bits (when the SNR/dB is about 5), to about 1.6 mutual information per bits (when the SNR/dB is about 10), to about 2.5 mutual information per bits (when the SNR/dB is about 15).

In some embodiments, the link quality parameter may be transmission power (e.g., optical transmission power). The optical power margin may be the reduction in optical transmission power for which the receiver may achieve the target error probability. The transmission power may be measured using, e.g., an optical power meter, a radiometer, a photometer, a laser power meter, a light meter, or any other suitable detector.

In some embodiments, an OLT may comprise: (i) a PMD receiver configured to receive one or more upstream signals from one or more ONUs, (ii) a detector configured to measure a link quality parameter in the one or more upstream signals; and (iii) a processing device. The processing device may be configured to identify a link quality parameter target. The value of the link quality parameter may be selected to achieve a target error probability. The processing device may be configured to adjust a burst parameter based on the link quality parameter target.

In some embodiments, the processing device may be configured to compute a link quality parameter margin between the measured link quality parameter and the link quality parameter target, and adjust the transmission parameter based on the link quality parameter margin.

In some embodiments, the link quality parameter may be a link quality parameter as disclosed herein. In one example, the link quality parameter may be one or more of an SNR, an SNR margin, a GMI, a GMI margin, an input BER, an output BER, or the like.

In some embodiments, the link quality parameter target may be a link quality parameter target as disclosed herein. That is, the link quality parameter target may be one or more of an error correction code (ECC) error probability, a packet error probability, a codeword error probability, a symbol error rate, or the like.

In some embodiments, for upstream burst mode the computed value of link quality parameters such as input BER, output BER, SNR, SNR margin, GMI, and GMI margin may change throughout duration of the burst, e.g., due to convergence effects of adaptive elements such as equalizers or timing recovery.

In some embodiments, performance may be monitored at a pre-defined position in time within the upstream burst to generate link quality parameters within a selected margin of error. Performance may be monitored in any suitable time window within the upstream burst, including in real-time, continuously, discretely, periodically, or the like. In one example, the time window may include one or more selected time points including: (i) one or more initial bits in a frame, (ii) one or more final bits in the frame, or (iii) a subset of bits in the frame.

In some examples, an ending time window of the upstream burst (i.e. a time window that extends from the end of the upstream burst towards the beginning of the upstream burst) may be measured when data is more probable at the end of the time window compared to the beginning of the time window. Measuring the ending time window of the upstream burst may provide a best case performance value.

In some examples, a beginning time window of the upstream burst (i.e. a time window that extends from the beginning of the upstream burst towards the ending of the upstream burst) may be measured. Measuring the starting time window of the upstream burst may provide a worst case performance value.

In some examples, an average may be obtained over the duration of the upstream burst. In some examples, discrete sections of the upstream burst may be measured. In some examples, an arbitrary subset (e.g., Tₛₜₐᵣₜ, . . . , Tₛₜₐᵣₜ+T bits) may be measured.

In some embodiments, the burst parameter may include one or more of a preamble pattern (including a preamble length) or a transmission burst length. Differences in the values of link quality parameters computed at different positions in the upstream burst may be used to adjust parameters such as the preamble length when burst setup flaws are detected. An optimized setting of the preamble length using position-dependent link quality parameters may increase the upstream throughput. A preamble that is short may reduce link quality because transmission errors may result in a lower transmission rate or in more conservative transmission parameter settings. In contrast, a long preamble may cause excessive overhead.

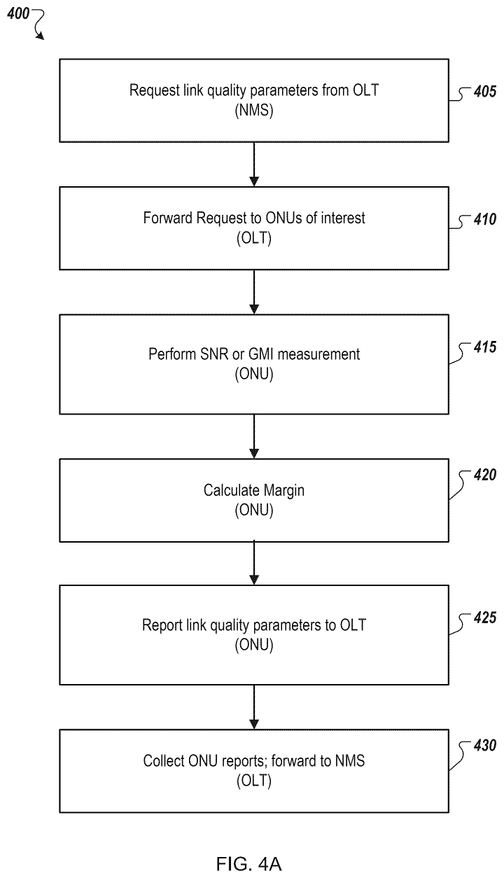

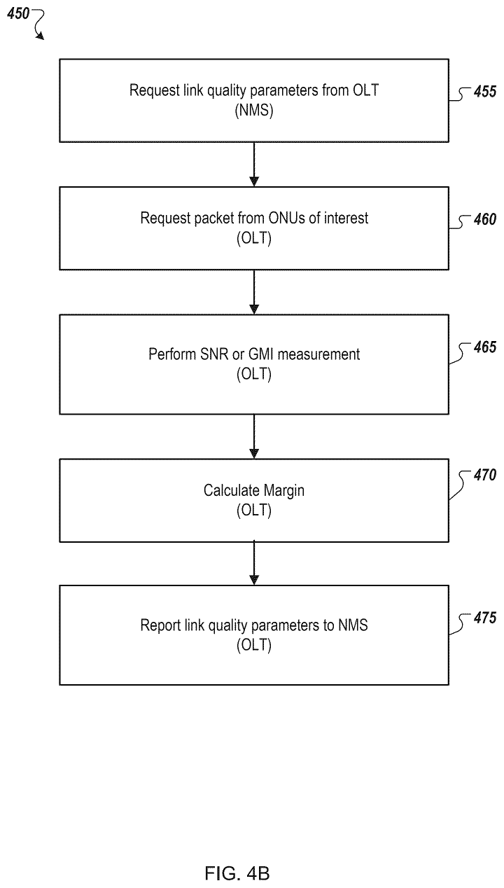

In some embodiments, as illustrated in FIG. 4A, the link quality parameters (e.g., SNR, GMI) and link quality parameter margins (e.g., SNR margin, GMI margin) may be measured at the receiver (e.g., ONU for downstream transmission, and OLT for upstream transmission).

In some embodiments, for downstream transmission, the link quality parameters and/or link quality parameter margins may be measured at the ONU. When the NMS requests link quality parameters and/or link quality parameter margins for downstream from the OLT, the OLT may request the link quality parameters and/or link quality parameter margins over the OC from the ONUs. The ONU receivers may perform the measurement, and the results may be reported over the OC back to the OLT.

In some embodiments, link quality parameter and link quality parameter margin reporting is illustrated by the operations 400 in FIG. 4A. At block 405, the NMS may request the link quality parameters from the OLT. AT block 410, the OLT may forward the request from the NMS to the ONUs of interest. At block 415, the ONU may perform the link quality parameter measurement (e.g., SNR, GMI measurement, or Tx power measurement). At block 420, the ONU may compute the link quality parameter margins (e.g., SNR margin, GMI margin, or Tx power margin). At block 425, the ONU may report the link quality parameters and the link quality parameter margins to the OLT. At block 430, the OLT may collect the ONU reports and forward the reports to the NMS.

In some embodiments, for upstream transmission, the link quality parameters and/or link quality parameter margins may be measured at the OLT which may request upstream transmissions from each ONU and performs the link quality parameter measurement at the OLT receiver for each ONU. The preamble (PSBu) pattern transmitted from the ONU to the OLT for link quality parameter measurement may be defined by the OLT. The length of the transmission burst may be defined by the OLT. The OLT may select a specific length of preamble and burst to increase the quality of the SNR measurement, e.g., by a sufficiently long transmission burst.

In some embodiments, link quality parameter and link quality parameter margin reporting is illustrated in FIG. 4B. At block 455, the NMS may request the link quality parameters and/or the link quality parameter margins from the OLT. AT block 460, the OLT may request packets from the ONUs of interest. At block 465, the OLT may perform the link quality parameter measurement (e.g., SNR or GMI measurement). At block 470, the OLT may compute the link quality parameter margins (e.g., SNR margin, GMI margin, or Tx power margin). At block 475, the OLT may report the link quality parameters and the link quality parameter margins to the NMS.

In some embodiments, based on the reported link quality parameter margins, an update of the transmission parameters such as, modulation settings, FEC settings, or transmit power settings, may be performed by an online reconfiguration (OLR) procedure. The OLR may be triggered by: (i) the receiver, which may monitors the link quality parameters continuously, or (ii) the NMS.

In some embodiments, the reconfiguration may be triggered by the receiver when a link quality parameter and/or link quality parameter margin is outside of the predefined bounds. In one example, an upper bound and a lower bound on the link quality parameter margin may be used. When the lower bound is violated, the transmission settings may be switched to a robust setting. When the upper bound is violated, the transmission settings may be switched to a throughput setting.

In another embodiment, a central optical node, e.g., the NMS or the OLT, may perform the reconfiguration or overrule the reconfiguration request from the receiver. When multiple receivers are served with the same transmission settings, e.g., for the downstream broadcast transmission, the central optical node (e.g., the NMS or the OLT) may select appropriate settings for multiple ONUs jointly.

In some embodiments, the NMS may collect one or more of the link quality parameters or link quality parameter margins (e.g., SNR, GMI, SNR margin, GMI margin, optical power, optical power margin) to monitor the link quality for the network. The collected parameters and/or margins may be used to identify and fix problems in the network and to configure the network.

In some embodiments, a method for online reconfiguration in a passive optical network may comprise performing, at a central optical node, a link quality parameter measurement. The method may comprise identifying, at the central optical node, a link quality parameter margin based on the link quality parameter measurement. The method may comprise computing, at the central optical node, an updated link setting based on the link quality parameter margin. The method may comprise applying the updated link setting. The central optical node may be one or more of a network management system (NMS) or an optical line terminal (OLT).

In some embodiments, the method may comprise computing, at the central optical node, the updated link setting based on the link quality parameter margin by: (i) identifying a lower bound violation when the link quality parameter margin is less than a lower bound; (ii) identifying an upper bound violation when the link quality parameter margin is greater than an upper bound; (iii) computing the updated link setting as a robust setting when the lower bound violation is identified; (iv) computing the updated link setting as a throughput setting when the upper bound violation is identified; and (v) computing the updated link setting as a previous setting when the lower bound violation is not identified and the upper bound violation is not identified;

In some embodiments, the method may comprise receiving, at the central optical node, an updated link setting request from the one or more ONUs, wherein the link setting request is based on a link quality parameter margin, and communicating, from the central optical node to the one or more ONUs, the updated link setting. In some embodiments, the updated link settings may include one or more of an updated error correction code (ECC) setting, an updated modulation type, an updated interleaver setting, an updated transmit power setting, or the like.

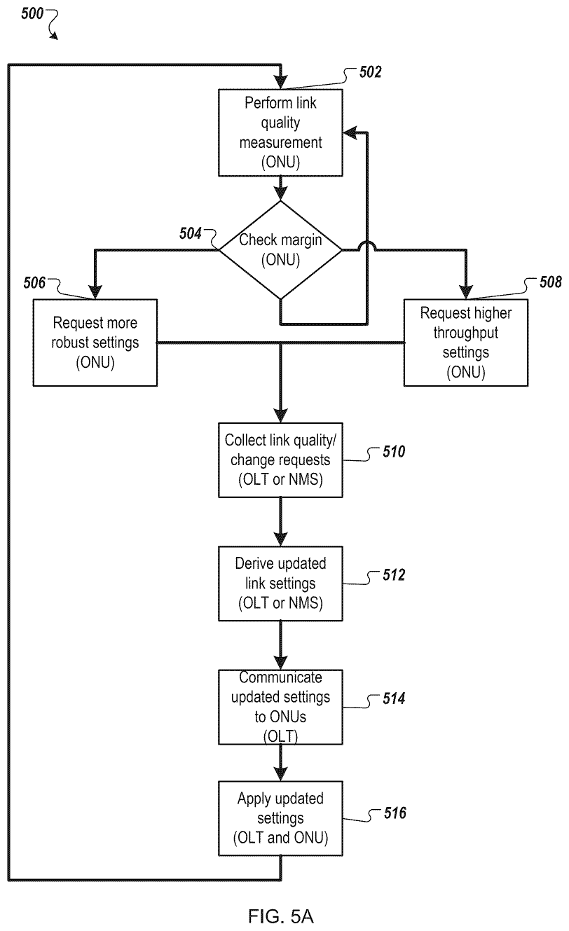

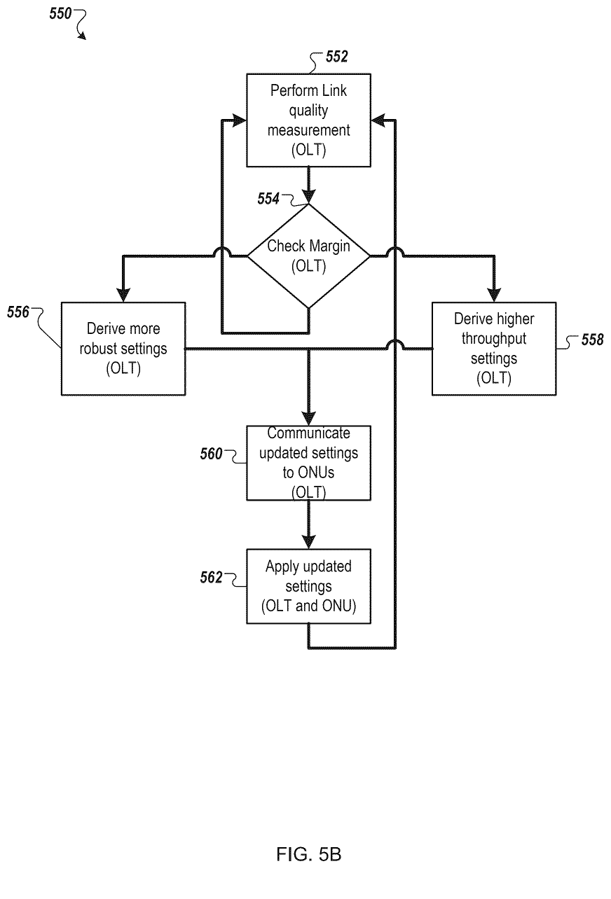

In some embodiments, as illustrated in FIG. 5A, functionality for downstream online reconfiguration may comprise an ONU configured to perform a link quality parameter measurement, as shown in operation 502. The ONU may be configured to check a link quality parameter margin, as shown in operation 504. When the link quality parameter margin exceeds an upper bound, the ONU may be configured to request higher throughput settings, as shown in operation 506. When the link quality parameter margin is less than a lower bound, the ONU may be configured to request more robust settings, as shown in operation 508. The link quality change requests may be collected by the OLT or NMS, as shown in operation 510. Updated link settings may be requested, as shown in operation 512. The updated link settings may be communicated to the ONUs by the OLT, as shown in operation 514. The updated settings may be applied by the OLT or ONU, as shown in operation 516. When the updated settings have been applied, operation 502 may be repeated.

In some embodiments, as illustrated in FIG. 5B, functionality for upstream online reconfiguration 550 may comprise an OLT configured to perform a link quality parameter measurement, as shown in operation 552. The OLT may be configured to check a link quality parameter margin, as shown in operation 554. When the link quality parameter margin exceeds an upper bound, the OLT may be configured to compute higher throughput settings, as shown in operation 558. When the link quality parameter margin is less than a lower bound, the OLT may be configured to compute more robust settings, as shown in operation 556. The updated link settings may be communicated to the ONUs by the OLT, as shown in operation 560. The updated settings may be applied by the OLT or ONU, as shown in operation 562. When the updated settings have been applied, operation 552 may be repeated.

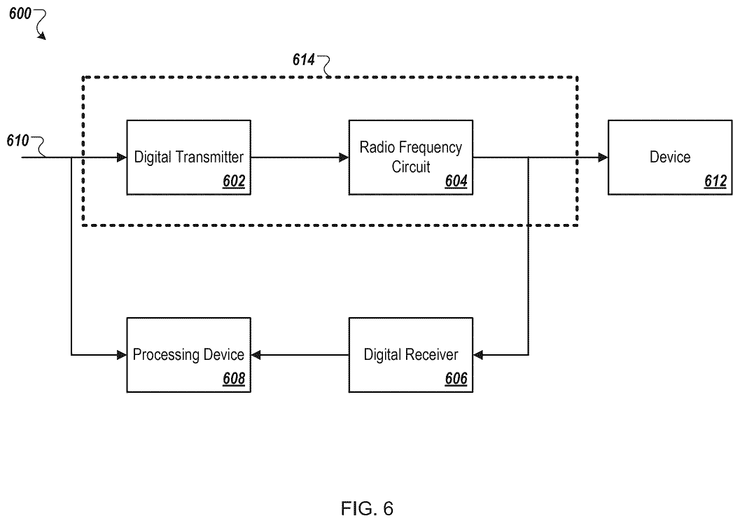

FIG. 6 illustrates a block diagram of an example communication system 600 in accordance with at least one embodiment described in the present disclosure. The communication system 600 may include a digital transmitter 602, a radio frequency circuit 604, a device 612, a digital receiver 606, and a processing device 608. The digital transmitter 602 and the processing device 608 may be configured to receive a baseband signal via connection 610. A transceiver 614 may comprise the digital transmitter 602 and the radio frequency circuit 604.

In some embodiments, the communication system 600 may include a system of devices that may be configured to communicate with one another via a wired or wireline connection. For example, a wired connection in the communication system 600 may include one or more Ethernet cables, one or more fiber-optic cables, and/or other similar wired communication mediums. Alternatively, or additionally, the communication system 600 may include a system of devices that may be configured to communicate via one or more wireless connections. For example, the communication system 600 may include one or more devices configured to transmit and/or receive radio waves, microwaves, ultrasonic waves, optical waves, electromagnetic induction, and/or similar wireless communications. Alternatively, or additionally, the communication system 600 may include combinations of wireless and/or wired connections. In these and other embodiments, the communication system 600 may include one or more devices that may be configured to obtain a baseband signal, perform one or more operations to the baseband signal to generate a modified baseband signal, and transmit the modified baseband signal, such as to one or more loads.

In some embodiments, the communication system 600 may include one or more communication channels that may communicatively couple systems and/or devices included in the communication system 600. For example, the transceiver 614 may be communicatively coupled to the device 612.

In some embodiments, the transceiver 614 may be configured to obtain a baseband signal. For example, as described herein, the transceiver 614 may be configured to generate a baseband signal and/or receive a baseband signal from another device. In some embodiments, the transceiver 614 may be configured to transmit the baseband signal. For example, upon obtaining the baseband signal, the transceiver 614 may be configured to transmit the baseband signal to a separate device, such as the device 612. Alternatively, or additionally, the transceiver 614 may be configured to modify, condition, and/or transform the baseband signal in advance of transmitting the baseband signal. For example, the transceiver 614 may include a quadrature up-converter and/or a digital to analog converter (DAC) that may be configured to modify the baseband signal. Alternatively, or additionally, the transceiver 614 may include a direct radio frequency (RF) sampling converter that may be configured to modify the baseband signal.

In some embodiments, the digital transmitter 602 may be configured to obtain a baseband signal via connection 610. In some embodiments, the digital transmitter 602 may be configured to up-convert the baseband signal. For example, the digital transmitter 602 may include a quadrature up-converter to apply to the baseband signal. In some embodiments, the digital transmitter 602 may include an integrated digital to analog converter (DAC). The DAC may convert the baseband signal to an analog signal, or a continuous time signal. In some embodiments, the DAC architecture may include a direct RF sampling DAC. In some embodiments, the DAC may be a separate element from the digital transmitter 602.

In some embodiments, the transceiver 614 may include one or more subcomponents that may be used in preparing the baseband signal and/or transmitting the baseband signal. For example, the transceiver 614 may include an RF front end (e.g., in a wireless environment) which may include a power amplifier (PA), a digital transmitter (e.g., 602), a digital front end, an Institute of Electrical and Electronics Engineers (IEEE) 1588v2 device, a Long-Term Evolution (LTE) physical layer (L-PHY), an (S-plane) device, a management plane (M-plane) device, an Ethernet media access control (MAC)/personal communications service (PCS), a resource controller/scheduler, and the like. In some embodiments, a radio (e.g., a radio frequency circuit 604) of the transceiver 614 may be synchronized with the resource controller via the S-plane device, which may contribute to high-accuracy timing with respect to a reference clock.

In some embodiments, the transceiver 614 may be configured to obtain the baseband signal for transmission. For example, the transceiver 614 may receive the baseband signal from a separate device, such as a signal generator. For example, the baseband signal may come from a transducer configured to convert a variable into an electrical signal, such as an audio signal output of a microphone picking up a speaker's voice. Alternatively, or additionally, the transceiver 614 may be configured to generate a baseband signal for transmission. In these and other embodiments, the transceiver 614 may be configured to transmit the baseband signal to another device, such as the device 612.

In some embodiments, the device 612 may be configured to receive a transmission from the transceiver 614. For example, the transceiver 614 may be configured to transmit a baseband signal to the device 612.

In some embodiments, the radio frequency circuit 604 may be configured to transmit the digital signal received from the digital transmitter 602. In some embodiments, the radio frequency circuit 604 may be configured to transmit the digital signal to the device 612 and/or the digital receiver 606. In some embodiments, the digital receiver 606 may be configured to receive a digital signal from the RF circuit and/or send a digital signal to the processing device 608.

In some embodiments, the processing device 608 may be a standalone device or system, as illustrated. Alternatively, or additionally, the processing device 608 may be a component of another device and/or system. For example, in some embodiments, the processing device 608 may be included in the transceiver 614. In instances in which the processing device 608 is a standalone device or system, the processing device 608 may be configured to communicate with additional devices and/or systems remote from the processing device 608, such as the transceiver 614 and/or the device 612. For example, the processing device 608 may be configured to send and/or receive transmissions from the transceiver 614 and/or the device 612. In some embodiments, the processing device 608 may be combined with other elements of the communication system 600.

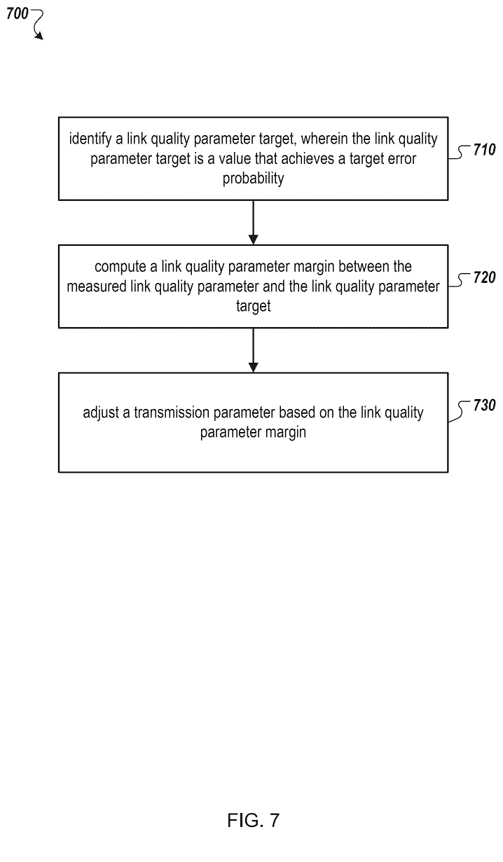

FIG. 7 illustrates a process flow of an example method 700 in a passive optical network, in accordance with at least one embodiment described in the present disclosure. The method 700 may be arranged in accordance with at least one embodiment described in the present disclosure.

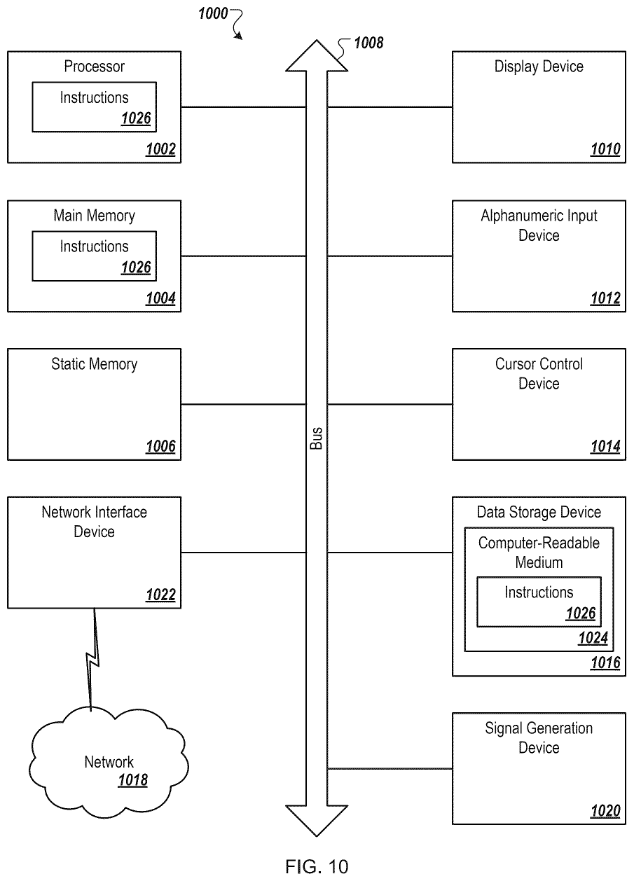

The method 700 may be performed by processing logic that may include hardware (circuitry, dedicated logic, etc.), software (such as is run on a computer system or a dedicated machine), or a combination of both, which processing logic may be included in the processing device 1002 of FIG. 10, the communication system 600 of FIG. 6, or another device, combination of devices, or systems.

The method 700 may begin at block 710 where the processing logic may identify a link quality parameter target, wherein the link quality parameter target is a value that achieves a target error probability.

At block 720, the processing logic may compute a link quality parameter margin between the measured link quality parameter and the link quality parameter target.

At block 730, the processing logic may adjust a transmission parameter based on the link quality parameter margin.

Modifications, additions, or omissions may be made to the method 700 without departing from the scope of the present disclosure. For example, in some embodiments, the method 700 may include any number of other components that may not be explicitly illustrated or described.

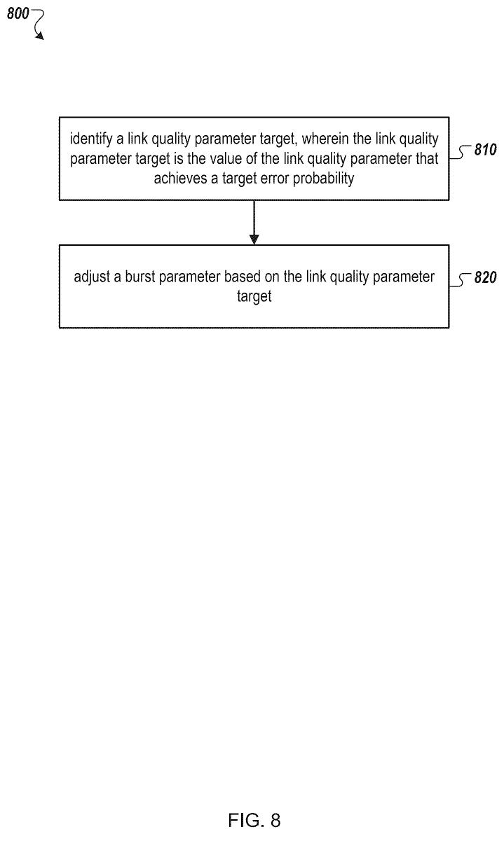

FIG. 8 illustrates a process flow of an example method 800 that may be used for a passive optical network, in accordance with at least one embodiment described in the present disclosure. The method 800 may be arranged in accordance with at least one embodiment described in the present disclosure.

The method 800 may be performed by processing logic that may include hardware (circuitry, dedicated logic, etc.), software (such as is run on a computer system or a dedicated machine), or a combination of both, which processing logic may be included in the processing device 1002 of FIG. 10, the communication system 600 of FIG. 6, or another device, combination of devices, or systems.

The method 800 may begin at block 810 where the processing logic may identify a link quality parameter target, wherein the link quality parameter target is the value of the link quality parameter that achieves a target error probability.

At block 820, the processing logic may adjust a burst parameter based on the link quality parameter target.

Modifications, additions, or omissions may be made to the method 800 without departing from the scope of the present disclosure. For example, in some embodiments, the method 800 may include any number of other components that may not be explicitly illustrated or described.

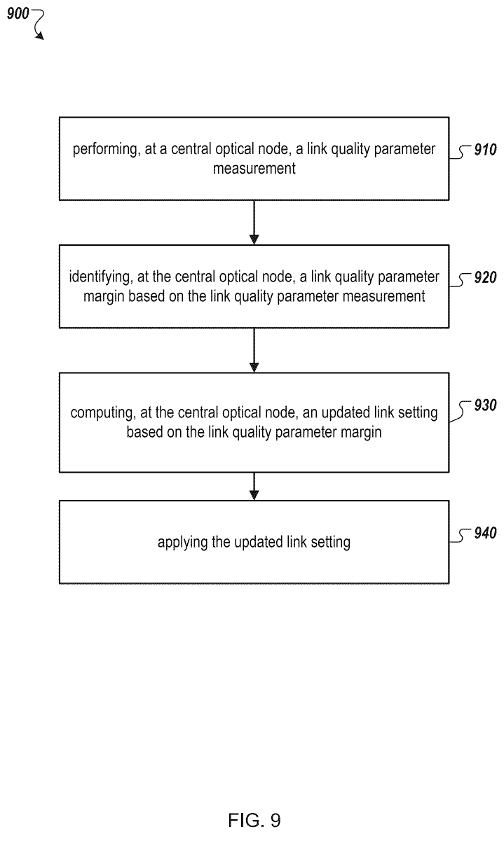

FIG. 9 illustrates a process flow of an example method 900 that may be used for online reconfiguration in a passive optical network, in accordance with at least one embodiment described in the present disclosure. The method 900 may be arranged in accordance with at least one embodiment described in the present disclosure.

The method 900 may be performed by processing logic that may include hardware (circuitry, dedicated logic, etc.), software (such as is run on a computer system or a dedicated machine), or a combination of both, which processing logic may be included in the processing device 1002 of FIG. 10, the communication system 600 of FIG. 6, or another device, combination of devices, or systems.

The method 900 may begin at block 910 where the processing logic may comprise performing, at a central optical node, a link quality parameter measurement.

At block 920, the processing logic may comprise identifying, at the central optical node, a link quality parameter margin based on the link quality parameter measurement.

At block 930, the processing logic may comprise computing, at the central optical node, an updated link setting based on the link quality parameter margin.

At block 940, the processing logic may comprise applying the updated link setting.

Modifications, additions, or omissions may be made to the method 900 without departing from the scope of the present disclosure. For example, in some embodiments, the method 900 may include any number of other components that may not be explicitly illustrated or described.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

FIG. 10 illustrates a diagrammatic representation of a machine in the example form of a computing device 1000 within which a set of instructions, for causing the machine to perform any one or more of the methods discussed herein, may be executed. The computing device 1000 may include a rackmount server, a router computer, a server computer, a mainframe computer, a laptop computer, a tablet computer, a desktop computer, or any computing device with at least one processor, etc., within which a set of instructions, for causing the machine to perform any one or more of the methods discussed herein, may be executed. In alternative embodiments, the machine may be connected (e.g., networked) to other machines in a LAN, an intranet, an extranet, or the Internet. The machine may operate in the capacity of a server machine in client-server network environment. Further, while only a single machine is illustrated, the term “machine” may also include any collection of machines that individually or jointly execute a set (or multiple sets) of instructions to perform any one or more of the methods discussed herein.

The example computing device 1000 includes a processing device (e.g., a processor) 1002, a main memory 1004 (e.g., read-only memory (ROM), flash memory, dynamic random access memory (DRAM) such as synchronous DRAM (SDRAM)), a static memory 1006 (e.g., flash memory, static random access memory (SRAM)) and a data storage device 1016, which communicate with each other via a bus 1008.

Processing device 1002 represents one or more general-purpose processing devices such as a microprocessor, central processing unit, or the like. More particularly, the processing device 1002 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 1002 may also include one or more special-purpose processing devices such as an application specific integrated circuit (ASIC), a field programmable gate array (FPGA), a digital signal processor (DSP), network processor, or the like. The processing device 1002 is configured to execute instructions 1026 for performing the operations and steps discussed herein.

The computing device 1000 may further include a network interface device 1022 which may communicate with a network 1018. The computing device 1000 also may include a display device 1010 (e.g., a liquid crystal display (LCD) or a cathode ray tube (CRT)), an alphanumeric input device 1012 (e.g., a keyboard), a cursor control device 1014 (e.g., a mouse) and a signal generation device 1020 (e.g., a speaker). In at least one embodiment, the display device 1010, the alphanumeric input device 1012, and the cursor control device 1014 may be combined into a single component or device (e.g., an LCD touch screen).

The data storage device 1016 may include a computer-readable storage medium 1024 on which is stored one or more sets of instructions 1026 embodying any one or more of the methods or functions described herein. The instructions 1026 may also reside, completely or at least partially, within the main memory 1004 and/or within the processing device 1002 during execution thereof by the computing device 1000, the main memory 1004 and the processing device 1002 also constituting computer-readable media. The instructions may further be transmitted or received over a network 1018 via the network interface device 1022.

While the computer-readable storage medium 1024 is shown in an example embodiment to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

In some embodiments, the different components, modules, engines, and services described herein may be implemented as objects or processes that execute on a computing system (e.g., as separate threads). While some of the systems and methods described herein are generally described as being implemented in software (stored on and/or executed by hardware), specific hardware implementations or a combination of software and specific hardware implementations are also possible and contemplated.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present disclosure have been described in detail, it should be understood that the various changes, substitutions, and alterations could be made hereto without departing from the spirit and scope of the present disclosure.

What is claimed is:

1. An optical network unit (ONU) in a passive optical network (PON), comprising:
a physical media dependent (PMD) receiver, at the ONU, configured to receive a downstream signal from an optical line terminal (OLT);
a detector configured to measure a link quality parameter in the downstream signal; and
a processing device configured to:
identify a link quality parameter target, wherein the link quality parameter target is a value that achieves a target error probability;
compute a link quality parameter margin between the measured link quality parameter and the link quality parameter target; and
adjust a transmission parameter based on the link quality parameter margin.

2. The ONU of claim 1, wherein the link quality parameter is one or more of a signal-to-noise ratio (SNR), a generalized mutual information (GMI), or a transmit power.

3. The ONU of claim 2, wherein the link quality parameter is the SNR measured based on one or more of an equalizer input signal, or an equalizer output signal.

4. The ONU of claim 2, wherein the link quality parameter is the GMI measured based on one or more of an equalizer input signal, an equalizer output signal, a demodulator output signal, a decoder input signal, an internal decoding parameter, or a decoder output signal.

5. The ONU of claim 2, wherein the link quality parameter is the SNR that has been computed based on GMI by using one or more of a channel capacity gap or a modulation-based reference curve.

6. The ONU of claim 5, wherein the ONU comprises a non-linear equalizer.

7. The ONU of claim 1, wherein the target error probability is one or more of a post forward error correction (FEC) error probability, a packet error probability, a codeword error probability, a symbol error rate, or a bit error rate.

8. The ONU of claim 1, wherein the transmission parameter is one or more of a modulation type, an error correction code (ECC) setting, an interleaver setting, or a transmit power setting.

9. The ONU of claim 1, wherein the processing device is further configured to:
measure the link quality parameter based on a transmit signal, wherein the transmit signal is determined by:
identifying a reference signal having an identifiable sequence,
applying a hard decision threshold to an output signal,
re-modulating a demodulator output signal, or
re-encoding a decoder output signal.

10. An optical line terminal (OLT) in a passive optical network (PON), comprising:
a physical media dependent (PMD) receiver, at the OLT, configured to receive one or more upstream signals from one or more optical network units (ONUs);
a detector, at the OLT, configured to measure a link quality parameter in the one or more upstream signals; and
a processing device configured to:
identify a link quality parameter target, wherein the link quality parameter target is the value of the link quality parameter that achieves a target error probability; and
adjust a burst parameter based on the link quality parameter target.

11. The OLT of claim 10, wherein the detector is further configured to:
measure the link quality parameter at one or more selected time points, wherein the time points are: one or more initial bits in a frame, one or more final bits in the frame, or a subset of bits in the frame.

12. The OLT of claim 10, wherein the burst parameter includes one or more of a preamble pattern or a transmission burst length.

13. The OLT of claim 10, wherein the link quality parameter is one or more of a signal-to-noise ratio (SNR), an SNR margin, a generalized mutual information (GMI), a GMI margin, an input bit error rate (BER), or an output BER.

14. The OLT of claim 10, wherein the link quality parameter target is one or more of an error correction code (ECC) error probability, a packet error probability, a codeword error probability, or a symbol error rate.

15. The OLT of claim 10, wherein the processing device is further configured to:
compute a link quality parameter margin between the measured link quality parameter and the link quality parameter target; and
adjust a transmission parameter based on the link quality parameter margin.

16. A method for online reconfiguration in a passive optical network, comprising:
performing, at a central optical node, a link quality parameter measurement;
identifying, at the central optical node, a link quality parameter margin based on the link quality parameter measurement;
computing, at the central optical node, an updated link setting based on the link quality parameter margin; and
applying the updated link setting.

17. The method of claim 16, further comprising:
computing, at the central optical node, the updated link setting based on the link quality parameter margin by:
identifying a lower bound violation when the link quality parameter margin is less than a lower bound;
identifying an upper bound violation when the link quality parameter margin is greater than an upper bound;
computing the updated link setting as a robust setting when the lower bound violation is identified;
computing the updated link setting as a throughput setting when the upper bound violation is identified; and
computing the updated link setting as a previous setting when the lower bound violation is not identified and the upper bound violation is not identified.

18. The method of claim 16, further comprising:
receiving, at the central optical node, an updated link setting request from one or more ONUs, wherein the link setting request is based on a link quality parameter margin; and
communicating, from the central optical node to the one or more ONUs, the updated link setting.

19. The method of claim 16, wherein the updated link settings include one or more of an updated error correction code (ECC) setting, an updated modulation type, an updated interleaver setting, or an updated transmit power setting.

20. The method of claim 16, wherein the central optical node is one or more of a network management system (NMS) or an optical line terminal (OLT).
